(19) United States
(12) Patent Application Publication
(10) Pub. No.: US 2026/0096255 A1
(43) Pub. Date: Apr. 2, 2026

(54) LIGHT-EMITTING DIODE CHIPS WITH METALLIC DIMMING LAYERS AND RELATED METHODS

(71) Applicant: CreeLED, Inc., Durham, NC (US)

(72) Inventors: Steven Wuester, Salemburg, NC (US); Michael Check, Holly Springs, NC (US); Nikolas Hall, Durham, NC (US)

(21) Appl. No.: 19/326,909

(22) Filed: Sep. 12, 2025

Related U.S. Application Data
(60) Provisional application No. 63/699,967, filed on Sep. 27, 2024.

(51) Int. Cl. H10H 20/841; H10H 20/01

(52) U.S. Cl. CPC H10H 20/841; H10H 20/034

(57) ABSTRACT

Solid-state lighting devices including light-emitting diodes (LEDs) and more particularly LED chips with metallic dimming layers and related methods are disclosed. Metallic dimming layers are formed over top surfaces and mesa sidewalls in LED chips to absorb and/or reflect light generated by the LED chips. Resulting LED chips have light outputs that may be reduced in a controlled manner to target various lighting applications where specific brightness levels are targeted. Metallic dimming layers are disclosed that extend past mesa sidewalls without extending all the way to perimeter edges of LED chips. Metallic dimming layers may be embedded within passivation layers for electrical isolation, particularly at the perimeter edges. Related methods are disclosed where LED chips with metallic dimming layers are fabricated with as few as three photolithography steps.

### RELATED APPLICATIONS

This application claims the benefit of provisional patent application Ser. No. 63/699,967, filed Sep. 27, 2024, the disclosure of which is hereby incorporated herein by reference in its entirety.

### FIELD OF THE DISCLOSURE

The present disclosure relates to solid-state lighting devices including light-emitting diodes (LEDs) and more particularly to LED chips with metallic dimming layers and related methods.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An active region may be fabricated, for example, from silicon carbide, gallium nitride, gallium phosphide, aluminum nitride, and/or gallium arsenide-based materials and/or from organic semiconductor materials. Photons generated by the active region are initiated in all directions.

As advancements in modern LED technology progress, the art continues to seek improved LEDs and solid-state lighting devices having desirable illumination characteristics capable of overcoming challenges associated with conventional devices.

### SUMMARY

The present disclosure relates to solid-state lighting devices including light-emitting diodes (LEDs) and more particularly to LED chips with metallic dimming layers and related methods. Metallic dimming layers are formed over top surfaces and mesa sidewalls in LED chips to absorb and/or reflect light generated by the LED chips. Resulting LED chips have light outputs that may be reduced in a controlled manner to target various lighting applications where specific brightness levels are targeted. Metallic dimming layers are disclosed that extend past mesa sidewalls without extending all the way to perimeter edges of LED chips. Metallic dimming layers may be embedded within passivation layers for electrical isolation, particularly at the perimeter edges. Related methods are disclosed where LED chips with metallic dimming layers are fabricated with as few as three photolithography steps.

In one aspect, an LED chip comprises: an active LED structure comprising an n-type layer, a p-type layer, and an active layer that is between the n-type layer and the p-type layer, the active LED structure forming a mesa with mesa sidewalls that define a perimeter of the active LED structure; an n-contact on a top side of the active LED structure and electrically connected to the n-type layer; a first passivation layer on the top side of the active LED structure and on the mesa sidewalls; and a metallic layer on the first passivation layer, the metallic layer extending from the n-contact to cover the mesa sidewalls, the metallic layer configured to absorb or reflect light generated by the active LED structure. The LED chip may further comprise a carrier submount, wherein the active LED structure is on the carrier submount in a position that is between the n-contact and the carrier submount. The LED chip may further comprise a second passivation layer on the metallic layer, wherein the first and second passivation layers extend to perimeter edges of the carrier submount and electrically isolate the metallic layer from the perimeter edges of the carrier submount. In certain embodiments, the metallic layer forms a lateral extension that extends on the first passivation layer in a direction from the mesa sidewalls toward the perimeter edges of the carrier submount. In certain embodiments, the lateral extension terminates before the perimeter edges of the carrier submount. In certain embodiments, a gap is formed between perimeter edges of the n-contact and the first and second passivation layers. In certain embodiments, the gap is formed between the perimeter edges of the n-contact and the metallic layer.

In certain embodiments, the LED chip may further comprise a barrier layer between the active LED structure and the carrier submount, the barrier layer extending to perimeter edges of the carrier submount. The LED chip may further comprise a current spreading layer on the p-type layer, wherein the barrier layer is directly on the current spreading layer, and wherein the current spreading layer and the barrier layer are between the active LED structure and the carrier submount.

In certain embodiments, the LED chip may further comprise: a current spreading layer on the p-type layer and a barrier layer directly on the current spreading layer, wherein the current spreading layer and the barrier layer are between the active LED structure and the carrier submount.

In certain embodiments, the barrier layer comprises a first sublayer that directly contacts the current spreading layer and a second sublayer on the first sublayer, wherein the first sublayer is discontinuous such that portions of the second sublayer directly contact the current spreading layer through the first sublayer. In certain embodiments, the barrier layer further comprises a third sublayer on the second sublayer, and the third sublayer is at least two times thicker than the second sublayer.

In certain embodiments, the metallic layer comprises a porous metallic layer. In certain embodiments, the metallic layer comprises titanium or platinum. In certain embodiments, the metallic layer extends continuously about an entire lateral perimeter of the n-contact on the active LED structure.

In another aspect, a method for fabrication of an LED chip comprises: etching a mesa with mesa sidewalls in an active LED structure, the active LED structure comprising an n-type layer, a p-type layer, and an active layer that is between the n-type layer and the p-type layer; depositing a first passivation layer on a top side of the active LED structure and on the mesa sidewalls; selectively depositing a metallic layer on portions of the first passivation layer, the metallic layer configured to absorb or reflect light generated by the active LED structure; and forming an n-contact on the top side of the active LED structure and electrically connected to the n-type layer by etching an opening through the first passivation layer and depositing the n-contact in the opening. In certain embodiments, etching the mesa comprises a first photolithography step, selectively depositing the metallic layer comprises a second photolithography step, and forming the n-contact comprises a third photolithography step. In certain embodiments, the LED chip is formed by no more than three photolithography steps.

The method may further comprise depositing a second passivation layer on the first passivation layer and the metallic layer, wherein etching the opening comprises etching through both the first passivation layer and the second passivation layer. In certain embodiments, selectively depositing the metallic layer comprises forming a lateral extension of the metallic layer on the first passivation layer, wherein the lateral extension extends away from the mesa sidewalls. In certain embodiments, the active LED structure is on a carrier submount and the lateral extension terminates before perimeter edges of the carrier submount. In certain embodiments, the first passivation layer extends to the perimeter edges of the carrier submount. In certain embodiments, the metallic layer extends continuously about an entire lateral perimeter of the n-contact on the active LED structure.

In another aspect, an LED chip comprises: an active LED structure comprising an n-type layer, a p-type layer, and an active layer that is between the n-type layer and the p-type layer, the active LED structure forming a mesa with mesa sidewalls that define a perimeter of the active LED structure; an n-contact on a top side of the active LED structure and electrically connected to the n-type layer; a current spreading layer on the p-type layer; and a barrier layer on the current spreading layer, the barrier layer comprising a first sublayer that directly contacts the current spreading layer and a second sublayer on the first sublayer, the first sublayer being discontinuous such that portions of the second sublayer directly contact the current spreading layer through the first sublayer. In certain embodiments, the barrier layer further comprises a third sublayer on the second sublayer, and the third sublayer is at least two times thicker than the second sublayer. The LED chip may further comprise a carrier submount, wherein the active LED structure is on the carrier submount in a position that is between the n-contact and the carrier submount, and wherein the current spreading layer and the barrier layer are between the active LED structure and the carrier submount. The LED chip may further comprise one or more bond layers between the carrier submount and the barrier layer. The LED chip may further comprise a passivation layer on the top side of the active LED structure and on the mesa sidewalls, and a metallic layer on the passivation layer, the metallic layer extending from the n-contact to cover the mesa sidewalls, the metallic layer being electrically isolated from the active LED structure.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a generalized cross-section of a light-emitting diode (LED) chip that embodies a vertical chip structure according to principles of the present disclosure.

FIG. 2 is a generalized schematic process flow for fabrication of the LED chip of FIG. 1.

FIGS. 3A to 3N provide cross-sectional views and various top side LED chip views and photomask views for a fabrication sequence for forming the LED chip of FIG. 1 similar to the process flow of FIG. 2.

FIG. 4 is a cross-sectional view of a portion of the LED chip of FIG. 1 illustrating details of the barrier layer for certain embodiments.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs) and more particularly to LED chips with metallic dimming layers and related methods. Metallic dimming layers are formed over top surfaces and mesa sidewalls in LED chips to absorb and/or reflect light generated by the LED chips. Resulting LED chips have light outputs that may be reduced in a controlled manner to target various lighting applications where specific brightness levels are targeted. Metallic dimming layers are disclosed that extend past mesa sidewalls without extending all the way to perimeter edges of LED chips. Metallic dimming layers may be embedded within passivation layers for electrical isolation, particularly at the perimeter edges. Related methods are disclosed where LED chips with metallic dimming layers are fabricated with as few as three photolithography steps.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds.

The active LED structure may be grown on a growth substrate that can include many materials, such as sapphire, SiC, aluminum nitride (AlN), GaN, with a suitable substrate being a 4H polytype of SiC, although other SiC polytypes can also be used including 3C, 6H, and 15R polytypes. SiC has certain advantages, such as a closer crystal lattice match to Group III nitrides than other substrates and results in Group III nitride films of high quality. SiC also has a very high thermal conductivity so that the total output power of Group III nitride devices on SiC is not limited by the thermal dissipation of the substrate. Sapphire is another common substrate for Group III nitrides and also has certain advantages, including being lower cost, having established manufacturing processes, and having good light transmissive optical properties.

Different embodiments of the active LED structure can emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example peak wavelengths primarily in a range from 400 nm to 700 nm.

In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. Near-IR and/or IR wavelengths for LED structures of the present disclosure may have wavelengths above 700 nm, such as in a range from 750 nm to 1100 nm, or more.

The LED chip can also be covered with one or more lumiphoric or other conversion materials, such as phosphors, such that at least some of the light from the LED chip is absorbed by the one or more phosphors and is converted to one or more different wavelength spectra according to the characteristic emission from the one or more phosphors. In some embodiments, the combination of the LED chip and the one or more phosphors emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof. Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. In some embodiments, one or more phosphors may include yellow phosphor (e.g., YAG:Ce), green phosphor (e.g., LuAg:Ce), and red phosphor (e.g., Ca_{i-x-y}SrₓEu_{y}AlSiN₃) and combinations thereof. One or more lumiphoric materials may be provided on one or more portions of an LED chip and/or a submount in various configurations. In certain embodiments, one or more surfaces of LED chips may be conformally coated with one or more lumiphoric materials, while other surfaces of such LED chips and/or associated submounts may be devoid of lumiphoric material. In certain embodiments, a top surface of an LED chip may include lumiphoric material, while one or more side surfaces of an LED chip may be devoid of lumiphoric material. In certain embodiments, all or substantially all outer surfaces of an LED chip (e.g., other than contact-defining or mounting surfaces) are coated or otherwise covered with one or more lumiphoric materials. In certain embodiments, one or more lumiphoric materials may be arranged on or over one or more surfaces of an LED chip in a substantially uniform manner. In other embodiments, one or more lumiphoric materials may be arranged on or over one or more surfaces of an LED chip in a manner that is non-uniform with respect to one or more of material composition, concentration, and thickness. In certain embodiments, the loading percentage of one or more lumiphoric materials may be varied on or among one or more outer surfaces of an LED chip. In certain embodiments, one or more lumiphoric materials may be patterned on portions of one or more surfaces of an LED chip to include one or more stripes, dots, curves, or polygonal shapes. In certain embodiments, multiple lumiphoric materials may be arranged in different discrete regions or discrete layers on or over an LED chip.

Light emitted by the active layer or region of an LED chip may typically travel in a variety of directions. For directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure may be useful for LED chips having a variety of geometries, such as vertical geometry. A vertical geometry LED chip typically includes anode and cathode connections on opposing sides or faces of the LED chip. In certain embodiments, a vertical geometry LED chip may also include a growth substrate that is arranged between the anode and cathode connections. In certain embodiments, LED chip structures may include a carrier submount and where the growth substrate is removed. In still further embodiments, any of the principles described may also be applicable to flip-chip structures where anode and cathode connections are made from a same side of the LED chip for flip-chip mounting to another surface.

Aspects of the present relate to solid-state lighting devices including light-emitting diodes (LEDs) and more particularly to a semi-transparent metallic layer deposited on an LED chip that can dim a light output of the LED chip. The metallic layer can be semi-transparent to wavelengths of light emitted by the LED chip. Standard sapphire-based LED chip alternatives struggle to meet binning requirements as the brightness is often too high. Aspects of the present disclosure provide a solution where an existing chip platform may include a titanium or other metal layer in place of etching passivation and texturing in order to provide chips with a range of brightnesses using the same chip platform. The thickness of the metal layer may be modified to provide different dimming levels, thus allowing a single LED chip platform to meet a variety of brightness requirements. Titanium (Ti) or platinum metal layers can be used since the metal layer adheres well to the passivation layers, and it can withstand gold etchants while still possessing light-blocking capabilities.

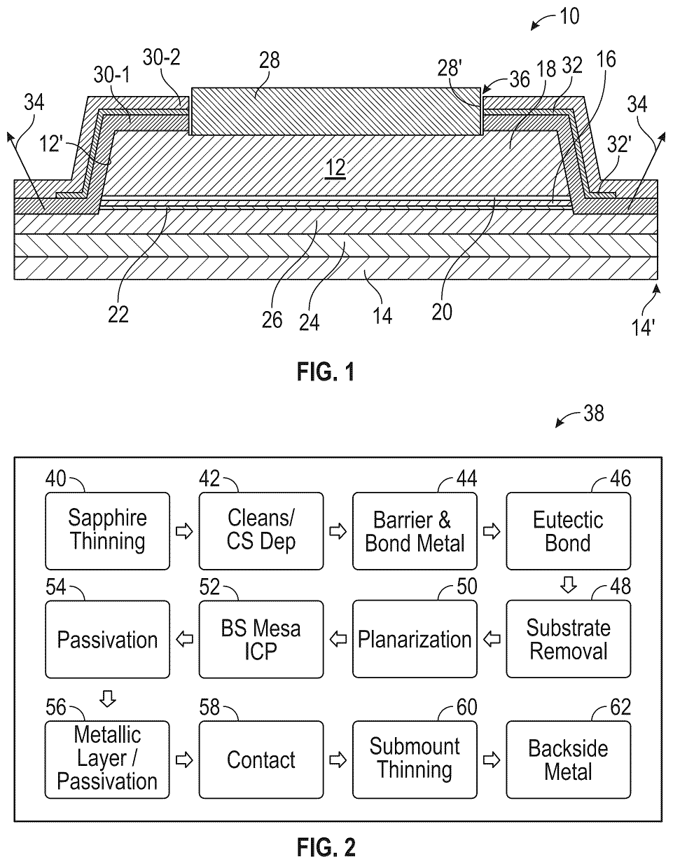

FIG. 1 is a generalized cross-section of an LED chip 10 that embodies a vertical chip structure according to principles of the present disclosure. The LED chip 10 includes an active LED structure 12 formed on a carrier submount 14. The active LED structure 12 generally refers to portions of the LED chip 10 that include semiconductor layers, such as epitaxial semiconductor layers, that form a structure that generates light when electrically activated. The active LED structure 12 is formed on and supported by the carrier submount 14 that can be made of many different materials, with a suitable material being silicon, or doped silicon. In certain embodiments, the carrier submount 14 comprises an electrically conductive material such that the carrier submount 14 is part of electrically conductive connections to the active LED structure 12. The active LED structure 12 may generally comprise a p-type layer 16, an n-type layer 18, and an active layer 20 arranged between the p-type layer 16 and the n-type layer 18. The active LED structure 12 may include many additional layers such as, but not limited to, buffer layers, nucleation layers, super lattice structures, un-doped layers, cladding layers, contact layers, current-spreading layers, and light extraction layers and elements. Additionally, the active layer 20 may comprise a single quantum well, a multiple quantum well, a double heterostructure, and/or super lattice structures. In FIG. 1, the p-type layer 16 is arranged between the active layer 20 and the carrier submount 14 such that the p-type layer 16 is closer to the carrier submount 14 than the n-type layer 18. In certain embodiments, a current spreading layer 22 may be provided between the p-type layer 16 and the carrier submount 14. The current spreading layer 22 may comprise a thin layer of a transparent conductive oxide such as indium tin oxide (ITO) or a thin metal layer such as platinum (Pt), although other materials may be used. In other embodiments, the doping order may be reversed such that the n-type layer 18 is arranged between the active layer 20 and the carrier submount 14.

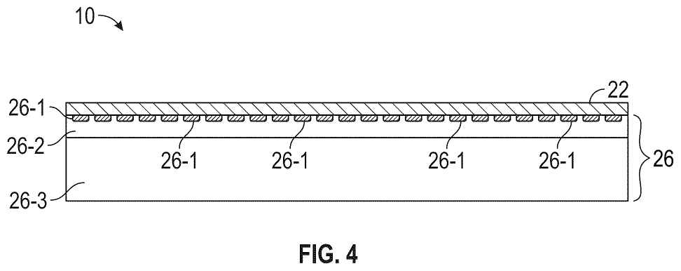

The active LED structure 12 may initially be formed by epitaxially growing or depositing the n-type layer 18, the active layer 20, and the p-type layer 16 sequentially on a growth substrate, followed by deposition of the current spreading layer 22 on the p-type layer 16. The active LED structure 12 may then be flipped and bonded to the carrier submount 14 by way of one or more bond metals 24 and the growth substrate is removed. A barrier layer 26 may be positioned between the bond metal 24 and the carrier submount 14. The barrier layer 26 may comprise an electrically conductive material that also prevents migration of other metals, such as from the bond metal 24, from reaching the active LED structure 12. Preventing this migration helps the LED chip 10 maintain efficient operation throughout its lifetime. The barrier layer 26 may comprise an electrically conductive material, with suitable materials including but not limited to Ti, Pt, nickel (Ni), gold (Au), chromium (Cr), tungsten (W), and combinations or alloys thereof. In certain embodiments, the barrier layer 26 is directly on the current spreading layer 22. Additional arrangements for the barrier layer 26 are described below in the context of FIG. 4.

An n-contact 28 is on a top surface of the active LED structure 12 and electrically connected to the n-type layer 18. The carrier submount 14 may comprise an electrically conductive material, such as p-type doped Si. Accordingly, the bottom surface of the carrier submount 14 forms a p-contact for the LED chip 10 that is electrically coupled to the p-type layer 16 by way of an electrical path formed by the bond metal 24, the barrier layer 26, and the current spreading layer 22. In this regard, the LED chip 10 may embody a vertical LED chip with anode and cathode connections made from opposing sides of the active LED structure 12. A first passivation layer 30-1 and a second passivation layer 30-2 are positioned on portions of the active LED structure 12 uncovered by the n-contact 28, including mesa sidewalls 12′ of the active LED structure 12. The first and second passivation layers 30-1, 30-2 serve to protect and provide electrical insulation for the LED chip 10. The first and second passivation layers 30-1, 30-2 may comprise many different materials, such as a dielectric material including but not limited to silicon nitride.

The LED chip 10 further includes a metallic layer 32 that is sandwiched between the first and second passivation layer 30-1, 30-2. The metallic layer 32 is formed of a material configured to absorb and/or reflect light generated by the active LED structure 12. The metallic layer 32 may be semi-transparent or partially opaque in various embodiments. Moreover, the metallic layer 32 may embody a continuous layer or a porous layer, depending on the amount of light intended to pass therethrough. The metallic layer 32 may also extend on the first passivation layer 30-1 to cover the mesa sidewalls 12′. In certain embodiments, the metallic layer 32 may have varying thicknesses, with a first thickness over the top of the active LED structure 12, and a second thickness proximate the mesa sidewalls 12′. The thicknesses of the metallic layer 32 over the active LED structure 12 and the mesa sidewalls 12′ may be selected based on a desired emission pattern or to make adjustments to the overall dimming level provided by the metallic layer 32. In certain embodiments, the metallic layer 32 may have a uniform thickness. The metallic layer 32 may comprise at least one of titanium or platinum, which are metals which adhere well to the first and second passivation layers 30-1, 30-2 as well as having the ability to withstand gold etchants.

In certain embodiments, the metallic layer 32 may be deposited over the first passivation layer 30-1 via sputter deposition or other forms of physical vapor deposition such as cathodic arc deposition, electron-beam physical vapor deposition, evaporative deposition, close-space sublimation, pulsed laser deposition, or pulsed electron deposition. A length of time of the deposition process can determine the thickness of the metallic layer 32, given a known deposition rate.

In certain embodiments, the metallic layer 32 may be patterned via a photomask in order to ensure the metallic layer 32 is not present in streets and areas of the LED chip 10 for the n-contact 28. In certain embodiments, the metallic layer 32 is electrically isolated from perimeter edges of the LED chip 10, such as areas vertically aligned with the perimeter edges 14′ of the carrier submount 14. In this regard, the metallic layer 32 may be patterned on the first passivation layer 30-1 such that the metallic layer 32 does not laterally extend all the way to perimeter edges 14′ of the carrier submount 14. By extending the first and second passivation layers 30-1, 30-2 to the perimeter edges 14′, the metallic layer 32 is effectively encapsulated by the first and second passivation layers 30-1, 30-2 so that the metallic layer 32 is electrically isolated from the active LED structure 12. Moreover, the metallic layer 32 may include a lateral extension 32′ that extends from the mesa sidewalls 12′ in a direction toward the perimeter edges 14′. The lateral extension 32′ of the metallic layer 32 may control how much light is permitted to escape the LED chip 10. For example, the n-contact 28 and the metallic layer 32 may effectively provide a blanket covering of reflective and/or absorbing material over the top of the active LED structure 12 and along the mesa sidewalls 12′. Accordingly, light 34 generated by the active LED structure 12 may primarily propagate along portions of the first passivation layer 30-1 and escape the LED chip 10 past the lateral extension 32′ of the metallic layer 32. By controlling a length of the lateral extension 32′, the amount of light permitted to escape may also be controlled.

In certain embodiments, a gap 36 may be formed between perimeter edges 28′ of the n-contact 28 and the metallic layer 32 as well as the first and second passivation layer 30-1, 30-2. The gap 36 may be controlled to be as small as possible to avoid forming too large of a pathway for light to escape along perimeter edges 28′ of the n-contact 28. In certain embodiments, the gap 36 provides electrical isolation between the metallic layer 32 and the n-contact 28. In other embodiments, the gap 36 is not continuous such that portions of the metallic layer 32 are electrically coupled with the n-contact 28. However, the remainder of the metallic layer 32 is effectively encapsulated by the first and second passivation layers 30-1, 30-2 to avoid electrical shorting.

FIG. 2 is a generalized schematic process flow 38 for fabrication of the LED chip 10 of FIG. 1. The process flow generally includes starting with an LED wafer having an active LED structure (i.e., 12 of FIG. 1) epitaxially grown on a growth substrate, such as a sapphire wafer. In a first step 40, the sapphire wafer may be subject to a thinning process, followed by second step 42 for cleaning and deposition of the current spreading layer (i.e., 22 of FIG. 1). As mentioned above, the current spreading layer may comprise ITO or other metals. In a third step 44, the barrier layer (i.e., 26 of FIG. 1) and the bond metal (i.e., 24 of FIG. 1) may then be formed on the current spreading layer. In a fourth step 46, the bond metal may be attached to the carrier submount (i.e., 14 of FIG. 1) by eutectic bonding. In a fifth step 48, the growth substrate of sapphire may be removed, followed by a sixth step 50 for planarization of the active LED structure (i.e., 12 of FIG. 1). In a seventh step 52, the active LED structure is etched to form a mesa with mesa sidewalls (i.e., 12′ of FIG. 1). In an eighth step 54, the first passivation layer (i.e., 30-1 of FIG. 1) is formed. In a ninth step 56, the metallic layer (i.e., 32 of FIG. 1) is formed on the first passivation layer. Moreover, the second passivation layer (i.e., 30-2 of FIG. 1) may also be provided. In a tenth step 58, the n-contact (i.e., 28 of FIG. 1) is formed. In an eleventh step 60, the carrier submount (i.e., 14 of FIG. 1) may be subjected to a thinning process, followed by a twelfth step 62 where a backside metal may be added to the carrier submount.

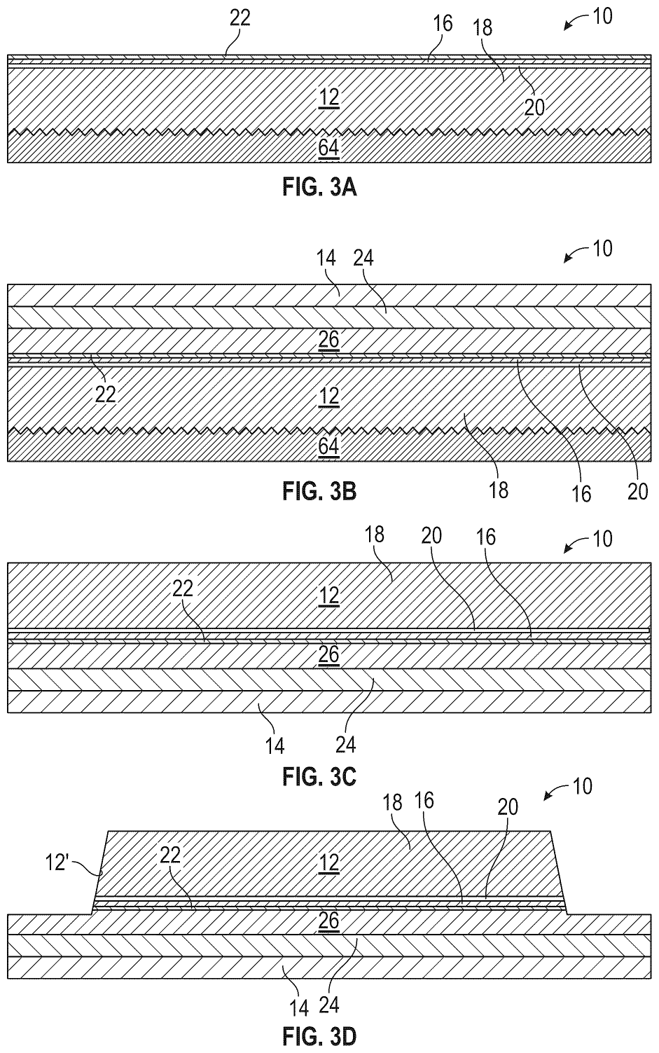

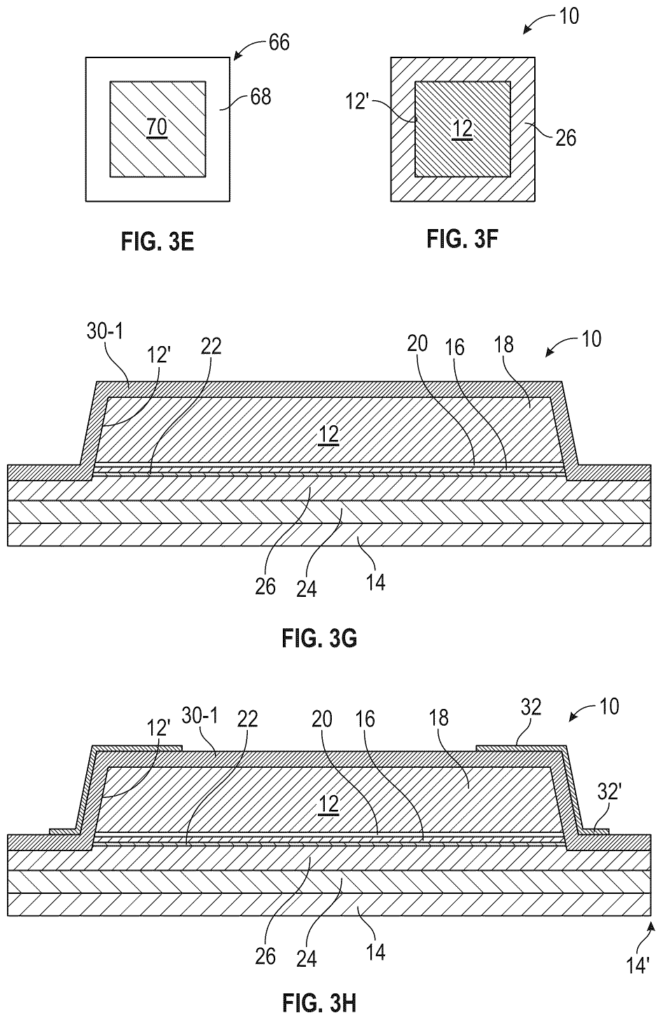

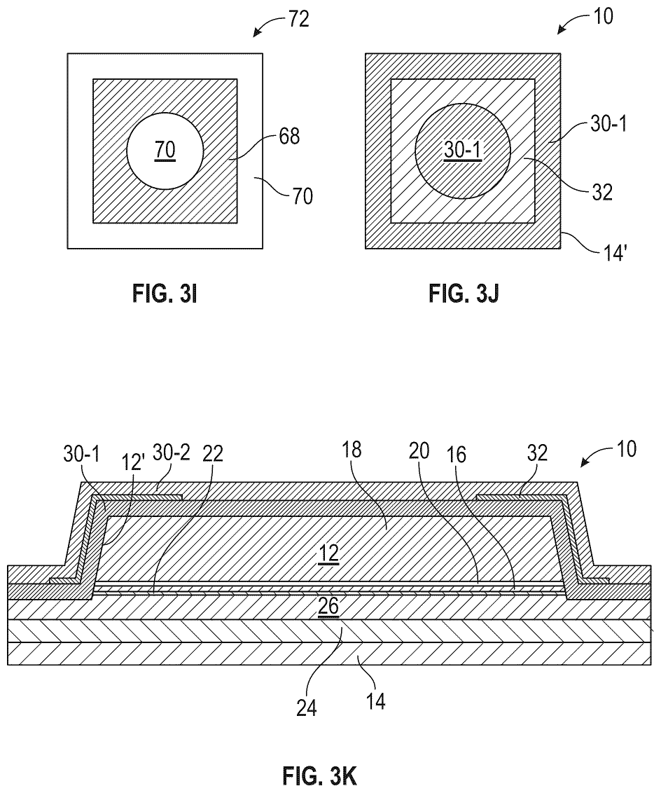

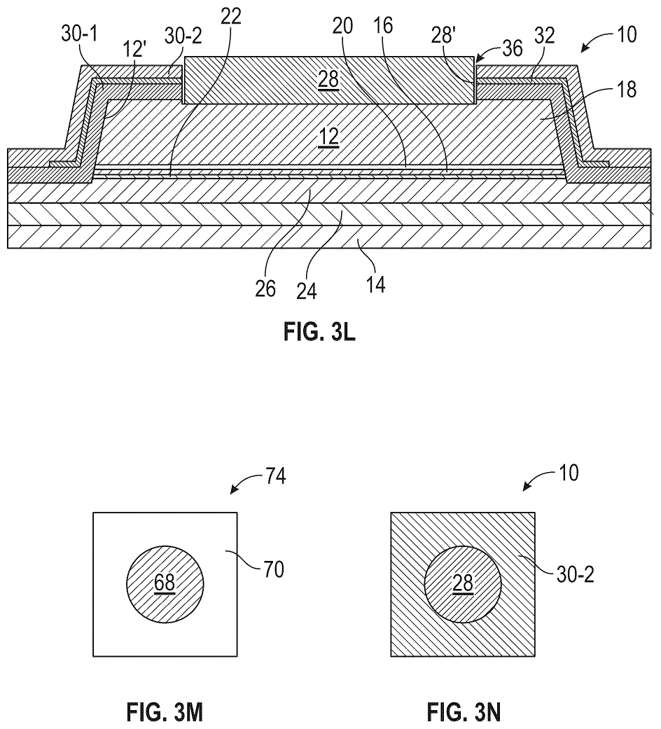

FIGS. 3A to 3N provide cross-sectional views and various top side views for a fabrication sequence for forming the LED chip 10 of FIG. 1 similar to the process flow 38 of FIG. 2.

FIG. 3A is a cross-sectional view of the LED chip 10 of FIG. 1 at a fabrication step where the active LED structure 12 and current spreading layer 22 are formed on a growth substrate 64. Accordingly, the fabrication step represented by FIG. 3A encompasses the steps 40 and 42 as described above for FIG. 2.

FIG. 3B is a cross-sectional view of the LED chip 10 of FIG. 3A at a subsequent fabrication step where the carrier submount 14 is bonded to the active LED structure 12 by way of the barrier layer 26 and the bond metal 24. As illustrated, the barrier layer 26 and the bond metal 24 are blanket deposited. Accordingly, the fabrication step represented by FIG. 3B encompasses the steps 44 and 46 as described above for FIG. 2.

FIG. 3C is a cross-sectional view of the LED chip 10 of FIG. 3B at a subsequent fabrication step where the growth substrate 64 of FIG. 3B is removed. Additionally, a planarization step may be applied to the active LED structure 12 to remove any undoped layers that may be present proximate the growth substrate 64 of FIG. 3B and expose a surface of the n-type layer 18. Accordingly, the fabrication step represented by FIG. 3C encompasses the steps 48 and 50 as described above for FIG. 2.

FIG. 3D is a cross-sectional view of the LED chip 10 of FIG. 3C at a subsequent fabrication step where the active LED structure 12 is etched to form a mesa with mesa sidewalls 12′. As illustrated, the barrier layer 26 may function as an etch stop for this step. Accordingly, the fabrication step represented by FIG. 3D encompasses the step 52 as described above for FIG. 2. Notably, this corresponds to a first photolithography step for the LED chip 10.

FIG. 3E is a top view of a first photomask 66 used in the etching step of FIG. 3D. The first photomask 66 may include an opening 68 corresponding to portions of the active LED structure 12 of FIG. 3D subject to etching and a mask portion 70 corresponding to unetched areas of the active LED structure 12.

FIG. 3F is a top view of the LED chip 10 of FIG. 3D from a similar perspective as the top view of the first photomask 66 of FIG. 3E. As illustrated, the active LED structure 12 forms a mesa with mesa sidewalls 12′ formed by etching and portions of the barrier layer 26 are exposed outside the mesa sidewalls 12′.

FIG. 3G is a cross-sectional view of the LED chip 10 of FIG. 3D at a subsequent fabrication step where the first passivation layer 30-1 is formed. As illustrated, the first passivation layer 30-1 is blanket deposited over the active LED structure 12, the mesa sidewalls 12′, and portions of the barrier layer 26 outside the mesa sidewalls 12′. Accordingly, the fabrication step represented by FIG. 3G encompasses the step 54 as described above for FIG. 2. In certain embodiments, the first passivation layer 30-1 may be deposited by atomic layer deposition, chemical vapor deposition, and combinations thereof.

FIG. 3H is a cross-sectional view of the LED chip 10 of FIG. 3G at a subsequent fabrication step where the metallic layer 32 is selectively deposited on portions of the first passivation layer 30-1. The metallic layer 32 is selectively deposited to cover portions of the first passivation layer 30-1 along the mesa sidewalls 12′. The metallic layer 32 is selectively deposited to also form the lateral extension 32′ that laterally extends on a portion of the first passivation layer 30-1 outside the mesa sidewalls 12′. The lateral extension 32′ extends toward the perimeter edge 14′ without extending all the way to the perimeter edge 14′ of the carrier submount 14. In this manner, formation of the metallic layer 32 proximate streets that separate individual LED chips is avoided since sawing of such streets if the metallic layer 32 were present may lead to leakage problems. Moreover, the metallic layer 32 may also not be formed along top portions of the active LED structure 12 where the n-contact 28 of FIG. 1 will later be formed. Accordingly, the metallic layer 32 may avoid exposure to etching steps associated with forming the n-contact 28 of FIG. 1 through the first passivation layer 30-1. The fabrication step represented by FIG. 3H encompasses a portion of the step 56 as described above for FIG. 2. Notably, this corresponds to a second photolithography step for the LED chip 10.

FIG. 3I is a top view of a second photomask 72 used in the selective deposition of the metallic layer 32 of FIG. 3H. The second photomask 72 may include the opening 68 corresponding to portions of the LED chip 10 of FIG. 3H where the metallic layer 32 is deposited. The mask portion 70 thereby corresponds to areas of the LED chip 10 where the metallic layer 32 is not deposited.

FIG. 3J is a top view of the LED chip 10 of FIG. 3H from a similar perspective as the top view of the second photomask 72 of FIG. 3I. As illustrated, the metallic layer 32 covers portions of the LED chip 10 as determined by the second photomask 72 without extending to the perimeter edge 14′. Moreover, the metallic layer 32 forms an opening corresponding to the mask portion 70 of FIG. 3I where the n-contact 28 of FIG. 3L will later be formed. Accordingly, the metallic layer 32 may be configured to extend continuously about an entire lateral perimeter of the n-contact 28 in certain embodiments.

FIG. 3K is a cross-sectional view of the LED chip 10 of FIG. 3H at a subsequent fabrication step where the second passivation layer 30-2 is formed. As illustrated, the second passivation layer 30-2 may be blanket deposited over the metallic layer 32. Accordingly, the fabrication step represented by FIG. 3K encompasses another portion of the step 56 as described above for FIG. 2. In certain embodiments, the second passivation layer 30-2 may be deposited in a similar manner as described above for the first passivation layer 30-1.

FIG. 3L is a cross-sectional view of the LED chip 10 of FIG. 3K at a subsequent fabrication step where the n-contact 28 is formed. An etching step may be performed through the first and second passivation layers 30-1, 30-2 to provide an opening for the n-contact 28. The n-contact 28 may then be deposited in the opening in a self-aligned manner. The gap 36 may be present due to etch undercutting. Accordingly, the fabrication step represented by FIG. 3L encompasses the step 58 as described above for FIG. 2. Notably, this corresponds to a third photolithography step for the LED chip 10. In certain embodiments, the metallic layer 32 extends continuously about an entire lateral perimeter of the n-contact 28 on the active LED structure 12.

FIG. 3M is a top view of a third photomask 74 used for the n-contact 28 of FIG. 3L. The third photomask 74 may include the opening 68 corresponding to the location of the n-contact 28 of FIG. 3H. The mask portion 70 thereby corresponds to areas of the LED chip 10 where the second passivation layer 30-2 is located.

FIG. 3N is a top view of the LED chip 10 of FIG. 3L from a similar perspective as the top view of the third photomask 74 of FIG. 3M. As illustrated, the n-contact 28 is formed centrally along the top of the LED chip 10. While a circular shape is illustrated, the n-contact 28 may comprise other shapes as determined by the third photomask 74 of FIG. 3M.

As described above with respect to FIGS. 3A to 3N, the LED chip 10 may be fabricated with as few as three photolithography steps. Accordingly, the LED chip 10 may be fabricated with reduced complexity and reduced associated costs.

FIG. 4 is a cross-sectional view of a portion of the LED chip 10 of FIG. 1 illustrating details of the barrier layer 26 for certain embodiments. The barrier layer 26 may embody a multiple layer structure with various metal layers. For example, a first sublayer 26-1 of the barrier layer 26 may comprise a discontinuous metal layer that is directly on the current spreading layer 22. A second sublayer 26-2 of the barrier layer 26 is then arranged to cover the first sublayer 26-1 and to contact portions of the current spreading layer 22 through the discontinuous regions of the second sublayer 26-2. In certain embodiments, a third sublayer 26-3 of the barrier layer 26 may be present to provide a bulk of the barrier layer 26. As described above with respect to FIGS. 3C and 3D, the barrier layer 26 may serve as an etch stop layer when the mesa and mesa sidewalls 12′ are formed at FIG. 3D.

The material of the first sublayer 26-1 may be selected to promote increased adhesion to the current spreading layer. In certain embodiments, the material of the first sublayer 26-1 may comprise Ni, or the material may only be Ni. However, such material may also be more prone to over etching during formation of the mesa sidewalls 12′ of FIG. 3D. In certain embodiments, the first sublayer 26-1 may be formed with a thickness intentionally selected to be discontinuous on the current spreading layer 22. For example, the thickness of the first sublayer 26-1 may be 50 angstroms or less. Despite being discontinuous, the first sublayer 26-1 may provide sufficient adhesion to the current spreading layer 22. The second sublayer 26-2 may then be formed to cover the first sublayer 26-1 and to contact portions of the current spreading layer 22 through the discontinuous regions of the second sublayer 26-2. The second sublayer 26-2 may be formed with a thickness in a range from 250 angstroms to 1000 angstroms, or a range from 250 angstroms to 500 angstroms. The material of the second sublayer 26-2, such as Cr, may be selected to provide enhanced etch resistance as compared with the first sublayer 26-1. In this manner, discontinuous portions of the first sublayer 26-1 may be effectively surrounded and/or encapsulated by the second sublayer 26-2 to provide shielding from etching. Accordingly, the combined structure of the first and second sublayers 26-1, 26-2 exhibits increased resistance to overetching that could otherwise delaminate the barrier layer 26 from the current spreading layer 22 and/or the p-type layer 16 of FIG. 1. In certain embodiments, the barrier layer 26 may further comprise the third sublayer 26-3, and the third sublayer 26-3 may constitute a bulk of the barrier layer 26. For example, the third sublayer 26-3 may have a thickness that is at least twice that of the second sublayer 26-2 for increased resistance of metal migration from the bond metal 24 of FIG. 1. In certain embodiments, the third sublayer 26-3 may comprise Ti, W, TiW, among others.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip, comprising:
an active LED structure comprising an n-type layer, a p-type layer, and an active layer that is between the n-type layer and the p-type layer, the active LED structure forming a mesa with mesa sidewalls that define a perimeter of the active LED structure;
an n-contact on a top side of the active LED structure and electrically connected to the n-type layer;
a first passivation layer on the top side of the active LED structure and on the mesa sidewalls; and
a metallic layer on the first passivation layer, the metallic layer extending from the n-contact to cover the mesa sidewalls, the metallic layer configured to absorb or reflect light generated by the active LED structure.

2. The LED chip of claim 1, further comprising a carrier submount, wherein the active LED structure is on the carrier submount in a position that is between the n-contact and the carrier submount.

3. The LED chip of claim 2, further comprising a second passivation layer on the metallic layer, wherein the first and second passivation layers extend to perimeter edges of the carrier submount and electrically isolate the metallic layer from the perimeter edges of the carrier submount.

4. The LED chip of claim 3, wherein the metallic layer forms a lateral extension that extends on the first passivation layer in a direction from the mesa sidewalls toward the perimeter edges of the carrier submount.

5. The LED chip of claim 4, wherein the lateral extension terminates before the perimeter edges of the carrier submount.

6. The LED chip of claim 3, wherein a gap is formed between perimeter edges of the n-contact and the first and second passivation layers.

7. The LED chip of claim 6, wherein the gap is formed between the perimeter edges of the n-contact and the metallic layer.

8. The LED chip of claim 2, further comprising a barrier layer between the active LED structure and the carrier submount, the barrier layer extending to perimeter edges of the carrier submount.

9. The LED chip of claim 8, further comprising a current spreading layer on the p-type layer, wherein the barrier layer is directly on the current spreading layer, and wherein the current spreading layer and the barrier layer are between the active LED structure and the carrier submount.

10. The LED chip of claim 9, wherein the barrier layer comprises a first sublayer that directly contacts the current spreading layer and a second sublayer on the first sublayer, wherein the first sublayer is discontinuous such that portions of the second sublayer directly contact the current spreading layer through the first sublayer.

11. The LED chip of claim 10, wherein the barrier layer further comprises a third sublayer on the second sublayer, and the third sublayer is at least two times thicker than the second sublayer.

12. The LED chip of claim 1, wherein the metallic layer comprises a porous metallic layer.

13. The LED chip of claim 1, wherein the metallic layer comprises titanium or platinum.

14. The LED chip of claim 1, wherein the metallic layer extends continuously about an entire lateral perimeter of the n-contact on the active LED structure.

15. A method for fabrication of a light-emitting diode (LED) chip, the method comprising:
etching a mesa with mesa sidewalls in an active LED structure, the active LED structure comprising an n-type layer, a p-type layer, and an active layer that is between the n-type layer and the p-type layer;
depositing a first passivation layer on a top side of the active LED structure and on the mesa sidewalls;
selectively depositing a metallic layer on portions of the first passivation layer, the metallic layer configured to absorb or reflect light generated by the active LED structure; and
forming an n-contact on the top side of the active LED structure and electrically connected to the n-type layer by etching an opening through the first passivation layer and depositing the n-contact in the opening.

16. The method of claim 15, wherein etching the mesa comprises a first photolithography step, selectively depositing the metallic layer comprises a second photolithography step, and forming the n-contact comprises a third photolithography step.

17. The method of claim 16, wherein the LED chip is formed by no more than three photolithography steps.

18. The method of claim 16, further comprising depositing a second passivation layer on the first passivation layer and the metallic layer, wherein etching the opening comprises etching through both the first passivation layer and the second passivation layer.

19. The method of claim 16, wherein selectively depositing the metallic layer comprises forming a lateral extension of the metallic layer on the first passivation layer, wherein the lateral extension extends away from the mesa sidewalls.

20. The method of claim 19, wherein the active LED structure is on a carrier submount, and the lateral extension terminates before perimeter edges of the carrier submount.

21. The method of claim 20, wherein the first passivation layer extends to the perimeter edges of the carrier submount.

22. The method of claim 16, wherein the metallic layer extends continuously about an entire lateral perimeter of the n-contact on the active LED structure.

23. A light-emitting diode (LED) chip, comprising:
an active LED structure comprising an n-type layer, a p-type layer, and an active layer that is between the n-type layer and the p-type layer, the active LED structure forming a mesa with mesa sidewalls that define a perimeter of the active LED structure;
an n-contact on a top side of the active LED structure and electrically connected to the n-type layer;
a current spreading layer on the p-type layer; and
a barrier layer on the current spreading layer, the barrier layer comprising a first sublayer that directly contacts the current spreading layer and a second sublayer on the first sublayer, the first sublayer being discontinuous such that portions of the second sublayer directly contact the current spreading layer through the first sublayer.

24. The LED chip of claim 23, wherein the barrier layer further comprises a third sublayer on the second sublayer, and the third sublayer is at least two times thicker than the second sublayer.

25. The LED chip of claim 24, further comprising a carrier submount, wherein the active LED structure is on the carrier submount in a position that is between the n-contact and the carrier submount, and wherein the current spreading layer and the barrier layer are between the active LED structure and the carrier submount.

26. The LED chip of claim 25, further comprising one or more bond layers between the carrier submount and the barrier layer.

27. The LED chip of claim 23, further comprising a passivation layer on the top side of the active LED structure and on the mesa sidewalls; and
a metallic layer on the passivation layer, the metallic layer extending from the n-contact to cover the mesa sidewalls, the metallic layer being electrically isolated from the active LED structure.
